(19) United States
(12) Patent Application Publication
(10) Pub. No.: US 2009/0230019 A1
(43) Pub. Date: Sep. 17, 2009

(54) Substrate cassette having electrode array

(75) Inventors: Cheng-AN Yang, Tainan County (TW); Chien-Li Ho, Tainan County (TW); Kung-Hsu Yeh, Tainan City (TW); Ming-Hung Huang, Kaohsiung County (TW)

Correspondence Address: BACON & THOMAS, PLLC, 625 SLATERS LANE, FOURTH FLOOR, ALEXANDRIA, VA, 22314-1176, US

(73) Assignee: CONTREL TECHNOLOGY CO., LTD., Tainan County (TW)

(21) Appl. No.: 12/213,249

(22) Filed: Jun. 17, 2008

(30) Foreign Application Priority Data
Mar. 11, 2008 (TW) 97108571

(51) Int. Cl. H01L 21/673; B65D 85/30

(52) U.S. Cl. 206/711; 206/722

(57) ABSTRACT

A substrate cassette having an electrode array includes a base frame, a plurality of first electrode plates, a plurality of second electrode plates, and a plurality of struts. The base frame includes at least one conductive member located at a bottom side thereof and each having a plurality of first channels and second channels parallel to the first channels. The first and second channels are alternately arranged. The base frame includes a plurality of fixtures located at a top side thereof. An insulator is mounted in each of the second channels. Each of the struts is mounted to two opposite sides of a bottom edge of each of the corresponding first and second electrode plates. The struts and the corresponding fixtures are vertically opposite to each other to jointly define a limited space for receiving substrates, wherein the struts carry the substrates. Therefore, the substrate cassette is applicable to the CVD process.

### BACKGROUND OF THE INVENTION

1. Field of the Invention

The present invention relates generally to cassettes for receiving plate-like materials, and more particularly, to a substrate cassette having an electrode array.

2. Description of the Related Art

A conventional substrate cassette includes receiving slots or spaces for receiving corresponding substrates respectively and the substrates are put into the cassette in upright or multi-layer stack arrangement.

The amorphous silicon thin film is the key to the production of the currently available non-crystalline silicon thin film solar cell. Presently, the amorphous silicon thin film solar cell is generally produced by plasma-enhanced chemical vapor deposition (PECVD). Specifically, one single substrate is put into a process chamber and then treated by chemical vapor deposition (CVD). However, it has not been available that multiple substrates can be simultaneously treated by the process of CVD at a time. Likewise, a cassette that is applicable to such process and can carry multiple substrates has not been available.

### SUMMARY OF THE INVENTION

The primary objective of the present invention is to provide a substrate cassette having an electrode array, which can carry multiple substrates and be applicable to the CVD process.

The secondary objective of the present invention is to provide a substrate cassette having an electrode array, in which the electrode array is applicable to insertion of multiple substrates.

The foregoing objectives of the present invention are attained by the substrate cassette having an electrode array for carrying a plurality of substrates. The cassette having an electrode array is composed of a base frame, a plurality of first electrode plates, a plurality of second electrode plates, and a plurality of struts. The base frame includes at least one conductive member at a bottom side thereof. Each of the at least one conductive member has a plurality of first channels and a plurality of second channels parallel to the first channels. The first and second channels alternately arranged in a predetermined interval. The base frame includes a plurality of fixtures located at a top side thereof and above the first and second channels. An insulator is mounted in each of the second channels. Each of the first electrode plates is installed in the base frame in such a way that its bottom edge is fixed into the corresponding first channel and its top edge is fixed to the corresponding fixture. Each of the second electrode plates is installed in the base frame in such a way that its bottom edge is fixed to the corresponding insulator and its top edge is fixed to the corresponding fixture. Each of the struts is mounted to two opposite sides of a bottom edge of the corresponding first electrode plate and to two opposite sides of a bottom edge of the corresponding second electrode plate. The struts and the corresponding fixtures are vertically opposite to each other to jointly define a limited space for receiving the substrates, wherein the struts carry the substrates.

### BRIEF DESCRIPTION OF THE DRAWINGS

FIG. 1 is a front schematic view of a preferred embodiment of the present invention.

FIG. 2 is a schematic view of the preferred embodiment of the present invention, illustrating that the relationship between the conductive members and the insulators.

FIG. 3 is a 3-D schematic view of the preferred embodiment of the present invention, illustrating the relationship of connection between the bottom side of the cassette and the second electrode plates.

FIG. 4 is a 3-D schematic view of the preferred embodiment of the present invention, illustrating the format of one of the second electrode plates.

FIG. 5 is a schematic view of the preferred embodiment of the present invention in operation, illustrating that the substrates are inserted into the first and second channels of the base frame.

### DETAILED DESCRIPTION OF PREFERRED EMBODIMENTS

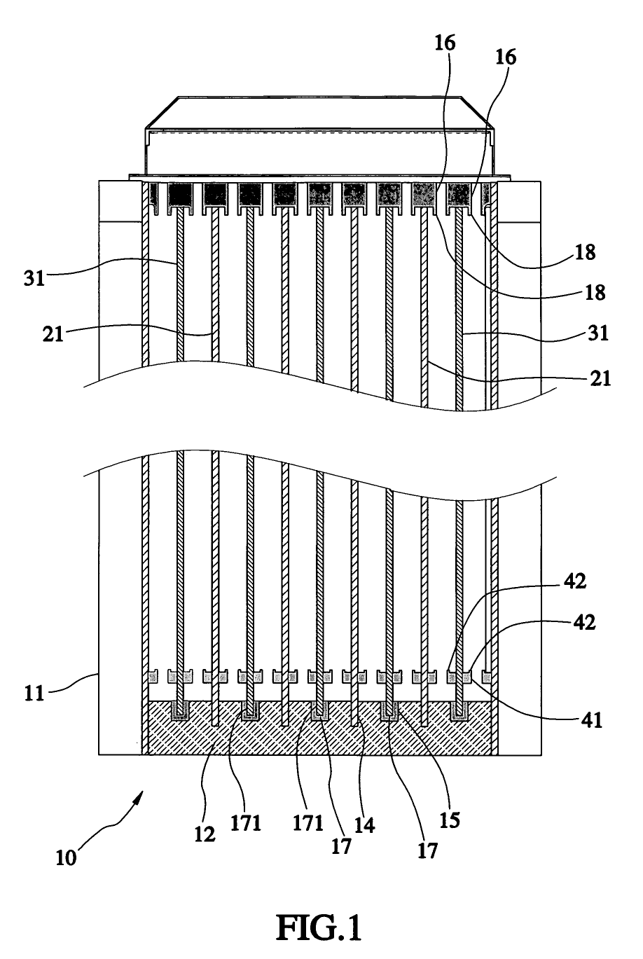

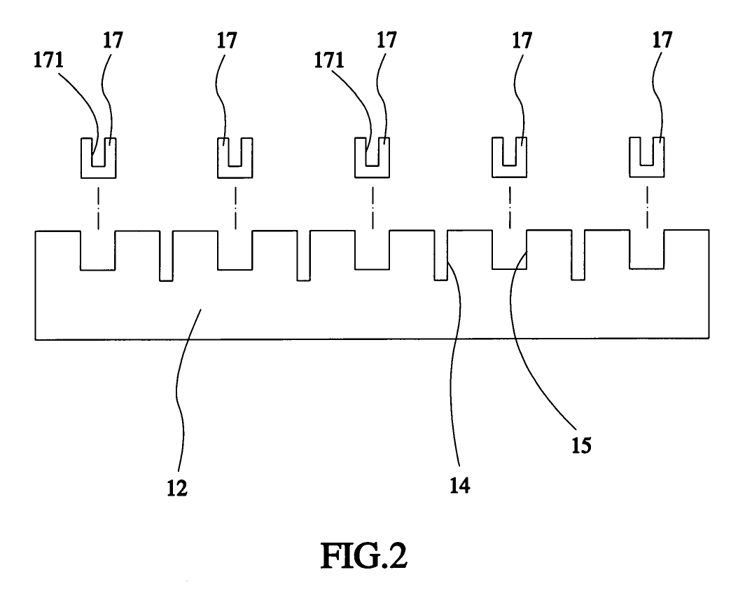

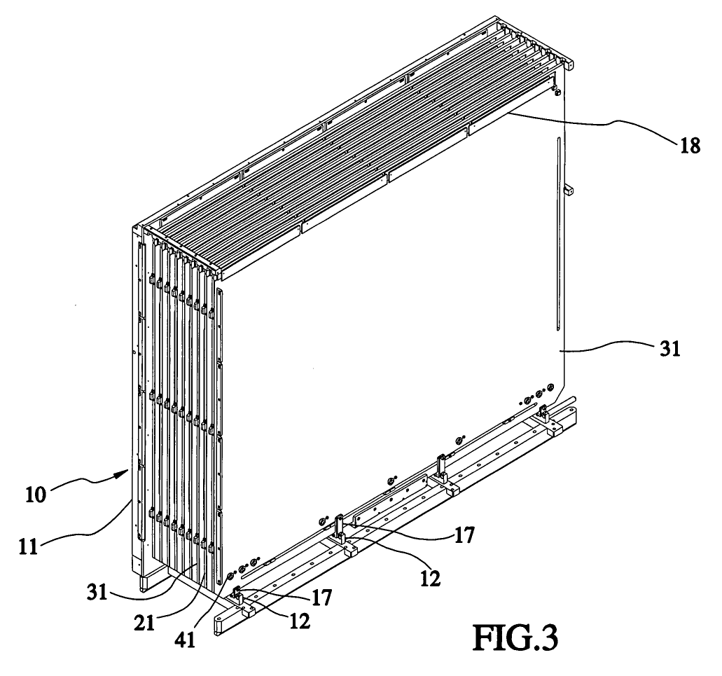

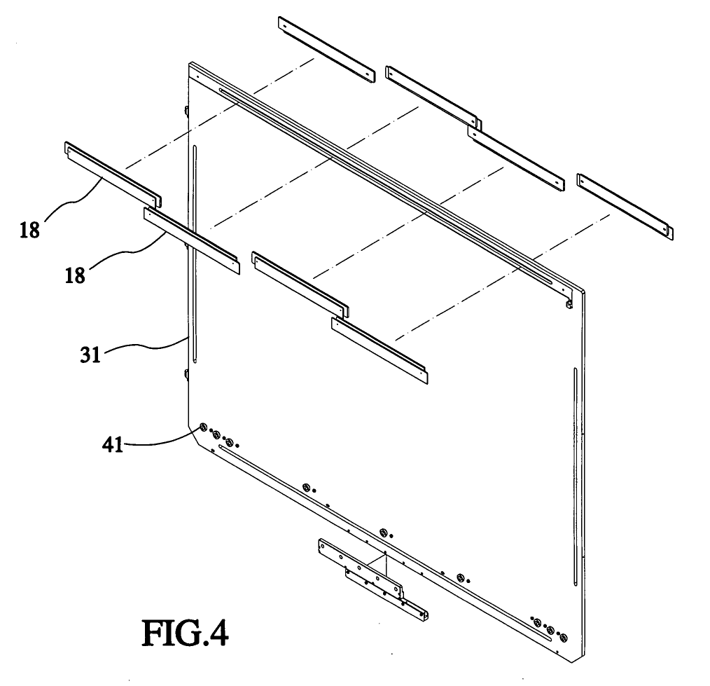

Referring to FIGS. 1-4, a substrate cassette 10 having an electrode array in accordance with a preferred embodiment of the present invention is composed of a base frame 11, a plurality of first electrode plates 21, a plurality of second electrode plates 31, and a plurality of struts 41.

The base frame 11 includes a plurality of conductive members 12 at a bottom side thereof. Each of the conductive members 12 has a plurality of first channels 14 and a plurality of second channels 15 parallel to the first channels. The first and second channels 14 and 15 are alternately arranged in such a way that they are spaced from each other in a predetermined interval. The base frame 11 also includes a plurality of fixtures 16 located at a top side thereof and above the first and second channels 14 and 15. The base frame 11 also includes a plurality of insulators 17 mounted in the corresponding second channels respectively. Each of the insulators 17 has a groove 171. Each of the fixtures 16 has two retaining portions 18 extending downward from two sides thereof respectively.

Each of the first electrode plates 21 is installed in the base frame 11 in such a way that its bottom edge is fixed into the corresponding first channel 14 and its top edge is fixed to the corresponding fixture 16 to be located between the two retaining portions 18.

Each of the second electrode plates 31 is installed in the base frame 11 in such a way that its bottom edge is fixed to the groove 171 of the corresponding insulator 17 and its top edge is fixed to the corresponding fixture 16 to be located between the two retaining portions 18.

Each of the struts 41 is mounted to two opposite sides of a bottom edge of the corresponding first electrode plate 21 and to two opposite sides of a bottom edge of the corresponding second electrode plate 31, having a stopping portion 42 extending upward from an external side thereof. The struts in this embodiment are wheel-shaped members, The struts 41 and the fixtures 16 are vertically opposite to each other to jointly define a limited space for receiving substrates (now shown) therein, wherein the struts 41 carry the substrates. When two substrates are mounted to two opposite sides of each of the first and second electrode plates 21 and 31, the two substrates are retained by the corresponding two retaining portions 18 and stopped by the corresponding two stopping portions 42 respectively.

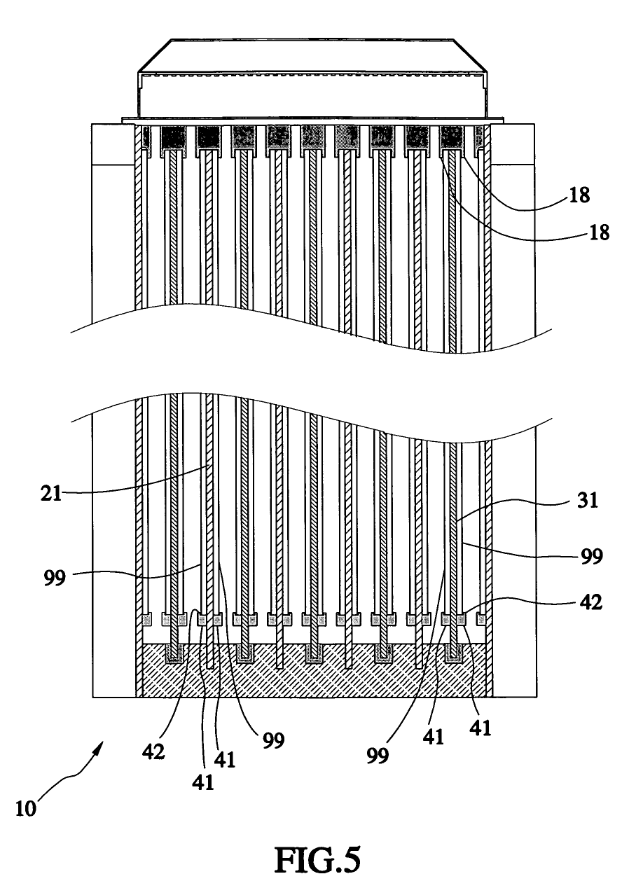

Referring to FIG. 5, after a plurality of the substrates 99 are put into the cassette 10 of the present invention, the substrates 99 are supported by the struts 41, stopped by the stopping portions 42, and retained by the retaining portions 18. In this way, the substrates 99 are held in fixed positions and also spaced from one another in a predetermined interval. Besides, the substrates 99 are arranged on the corresponding first and second electrode plates 21 and 31, such that the cassette 10 carrying the multiple substrates 99 can be treated by the CVD process.

In conclusion, the present invention includes the following advantages.
1. It can carry multiple substrates and be applicable to the CVD process.
2. It can be inserted by multiple substrates therein for further treatment of the CVD process.

Although the present invention has been described with respect to a specific preferred embodiment thereof, it is no way limited to the details of the illustrated structures but changes and modifications may be made within the scope of the appended claims.

What is claimed is:

1. A substrate cassette having an electrode array for carrying a plurality of substrates, comprising:
a base frame having at least one conductive member at a bottom side thereof, each of said at least one conductive member having a plurality of first channels and a plurality of second channels parallel to said first channels, said first and second channels being alternately arranged in a predetermined interval, said base frame having a plurality of fixtures located at a top side thereof and above said first and second channels, an insulator being mounted in each of said second channels;
a plurality of first electrode plates, each of said first electrode plates being mounted to said base frame in such a way that its bottom edge is fixed into the corresponding one of said first channels and its top edge is fixed to the correspond one of the said fixtures;
a plurality of second electrode plates, each of said second electrode plates being mounted to said base frame in such a way that its bottom edge is fixed into the corresponding one of said insulators and its top edge is fixed to the correspond one of said fixtures; and
a plurality of struts, each of said struts being mounted to two opposite sides of a bottom edge of the corresponding one of said first electrodes and to two opposite sides of a bottom edge of the corresponding one of said second electrodes, said struts and said fixtures being vertically opposite to each other to jointly define a limited space for receiving said substrate therein, said struts carrying said substrates.

2. The substrate cassette as defined in claim 1, wherein each of said insulators comprises a groove; and each of said second electrode plates is mounted in the corresponding one of said grooves.

3. The substrate cassette as defined in claim 1, wherein each of said fixtures comprises two retaining portions extending downward from two sides thereof respectively; and each of said first and second electrode plates is located between said two retaining portions of the correspond one of said fixtures.

4. The substrate cassette as defined in claim 3, wherein when two substrates are mounted to two opposite sides of each of said first and second electrode plates respectively, said two substrates are held in fixed positions by the corresponding two of said retaining portions of said fixtures.

5. The substrate cassette as defined in claim 1, wherein each of said struts comprises a stopping portion extending upward from an external side thereof.
